(19) United States
(12) Patent Application Publication
(10) Pub. No.: US 2019/0355509 A1
(43) Pub. Date: Nov. 21, 2019

(54) HEAT RADIATING SHEET FOR WIRELESS CHARGING AND ELECTRONIC DEVICE HAVING THE SAME

(71) Applicant: WITS Co., Ltd., Yongin-si (KR)

(72) Inventors: Soon Joung YIO, Suwon-si (KR); Hee Seung KIM, Suwon-si (KR); Jae Hyuk JANG, Suwon-si (KR); Young Seung ROH, Suwon-si (KR); Byoung Woo RYU, Suwon-si (KR); Young Ho KIM, Suwon-si (KR); Jae Sun WON, Suwon-si (KR)

(73) Assignee: WITS Co., Ltd., Yongin-si (KR)

(21) Appl. No.: 16/160,266

(22) Filed: Oct. 15, 2018

(30) Foreign Application Priority Data
May 15, 2018 (KR) 10-2018-0055445

(51) Int. Cl. H01F 27/28; H01F 38/14; H02J 50/10; H02J 7/02

(52) U.S. Cl. CPC H01F 27/2876; H01F 38/14; H01F 27/365; H02J 7/025; H02J 50/10

(57) ABSTRACT

An electronic device includes a power module that transmits or receives power wirelessly and includes a coil portion that generates a magnetic field; and a heat radiating sheet disposed on one side of the power module. The heat radiating sheet includes line-type conductors arranged to overlap the coil portion and an area-type conductor disposed along a periphery of the line-type conductors.

### CROSS-REFERENCE TO RELATED APPLICATION

This application claims the benefit under 35 USC 119(a) of Korean Patent Application No. 10-2018-0055445 filed on May 15, 2018 in the Korean Intellectual Property Office, the entire disclosure of which is incorporated herein by reference for all purposes.

### BACKGROUND

### 1. Field

The following description relates to a heat radiating sheet used for wireless charging and an electronic device having the same.

### 2. Description of Related Art

Wireless transmissions technology is being widely applied to various electronic devices, including various communication/portable terminals such as smartphones and wearable devices.

In order for an electronic device to realize such a wireless transmissions technology, a heat dissipation method of a coil for wireless transmissions is required.

When a normal conductive heat radiating sheet is used, an eddy current may be generated due to transmission of electromagnetic waves, and current loss may occur due to the eddy current.

The current loss due to the eddy current may cause the efficiency of wireless transmissions to be extremely low or may generate a new hot spot.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, an electronic device includes a power module that transmits or receives power wirelessly and includes a coil portion that generates a magnetic field; and a heat radiating sheet disposed on one side of the power module. The heat radiating sheet includes line-type conductors arranged to overlap the coil portion and an area-type conductor disposed along a periphery of the line-type conductors.

The heat radiating sheet may include a cutting portion including a cut in a radial direction of the area-type conductor.

The area-type conductor may be electrically connected to ground.

The heat radiating sheet may include an insulating layer attached to the line-type conductors and the area-type conductor.

The line-type conductors may include first line-type conductors attached to a first surface of the insulating layer and second line-type conductors attached to a second surface of the insulating layer, and the area-type conductor may include a first area-type conductor attached to the first surface of the insulating layer and a second area-type conductor attached to the second surface of the insulating layer.

The first line-type conductors and the second line-type conductors may face in different directions.

The heat radiating sheet may include an interlayer connection conductor electrically connecting the first area-type conductor and the second area-type conductor.

One end of each of the line-type conductors may be connected to the area-type. conductor.

The line-type conductors may each include a first end and a second end opposite the first end, and the line-type conductors may be arranged such that first line-type conductors having the first end connected to the area-type conductor are alternated with second line-type conductors having the second end connected to the area-type conductor.

Each of the line-type conductors may have a line width of 200 μm or less.

The line-type conductors and the area-type conductor may be formed of a same material.

The line-type conductors may be spaced apart from each other so as not to contact each other.

The electronic device may include a case configured to accommodate the coil portion and the heat radiating sheet therein. A first surface of the heat radiating sheet may be attached to an internal surface of the case and a second surface of the heat radiating sheet may be attached to the coil portion.

In another general aspect, a heat radiating sheet for wireless charging disposed between a power transmitting module and a power receiving module. The heat radiating sheet includes an insulating layer, first line-type conductors disposed on a first surface of the insulating layer and electrically disconnected from each other, and second line-type conductors disposed on a second surface of the insulating layer and electrically disconnected from each other, and electrically disconnected from the first line-type conductors.

The first line-type conductors may be arranged to have longitudinal axes in a first direction and the second line-type conductors may be arranged to have longitudinal axes directed in a second direction that is different from the first direction.

An area-type conductor may be disposed along a periphery of either the first line-type conductors or a periphery of the second line-type conductors.

The area-type conductor may have a cut in a radial direction of the area-type conductor.

In another general aspect, an apparatus includes a coil layer including coil wiring configured to generate a magnetic field, a magnetic layer disposed on a first surface of the coil layer, an insulating layer disposed on a second surface of the coil layer; and a conductive layer including line-type conductors disposed parallel to each other on the insulating layer and arranged to overlap the coil wiring.

The conductive layer may include an area-type conductor disposed on the insulating layer and arranged along a periphery of an area in which the line-type conductors overlap the coil wiring.

A cutting portion may cut the area-type conductor in a radial direction, and the cutting portion may be a linear slit connecting the area in which the line-type conductors overlap the coil wiring and an area outside of the area-type conductor.

### BRIEF DESCRIPTION OF DRAWINGS

FIG. 1 is a perspective view schematically showing an electronic device according to an example.

FIG. 2 is a cross-sectional view taken along line I-I′ of FIG. 1.

FIG. 3 is a plan view schematically showing the heat radiating sheet shown in FIG. 1.

FIG. 4 is a cross-sectional view taken along line II-II′ of FIG. 3.

FIGS. 5A and 5B are a plan view and a rear view illustrating a heat radiating sheet according to an example.

FIG. 6 is a cross-sectional view taken along line III-III′ of FIG. 5A.

FIGS. 7A and 7B are a plan view and a rear view illustrating a heat radiating sheet according to an example.

FIGS. 8A and 8B are a plan view and a rear view illustrating a heat radiating sheet according to an example.

FIGS. 9A and 9B are a plan view and a rear view illustrating a heat radiating sheet according to an example.

FIG. 10 is a cross-sectional view taken along line IV-IV′ of FIG. 9A.

FIG. 11 is a cross-sectional view schematically showing an electronic device according to an example.

FIG. 12 is a cross-sectional view schematically showing a heat radiating sheet according to an example.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Herein, it is noted that use of the term “may” with respect to an example or embodiment, e.g., as to what an example or embodiment may include or implement, means that at least one example or embodiment exists in which such a feature is included or implemented while all examples and embodiments are not limited thereto.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

In describing the examples, a wireless charging device collectively refers to a power transmission module transmitting power and a power receiving module receiving and storing power.

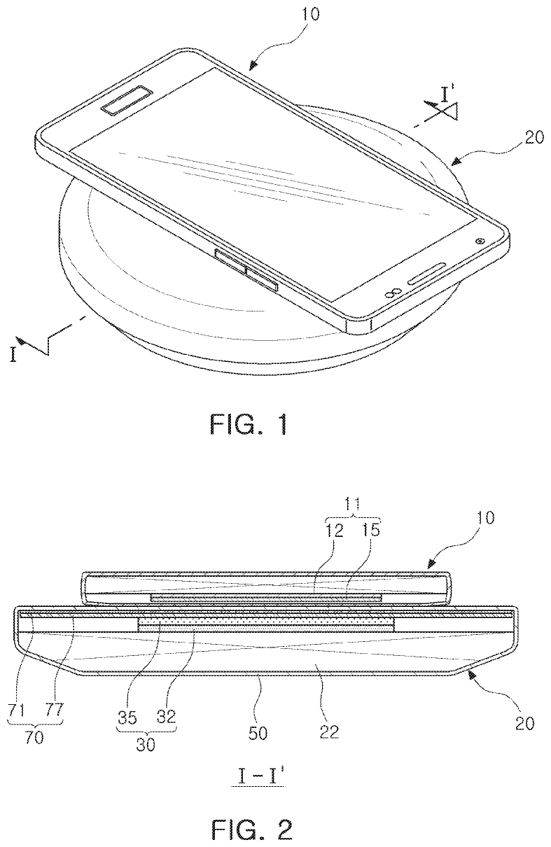

FIG. 1 is a perspective view schematically showing an electronic device according to an example. FIG. 2 is a cross-sectional view taken along line I-I′ of FIG. 1.

Referring to FIGS. 1 and 2, the electronic device according to an example is a wireless charging device, which may include a wireless power transmission device wirelessly transmitting power or a wireless power reception device wirelessly receiving and storing power. In the example, the wireless power transmission device includes a charging device 20, and the wireless power reception device includes a portable terminal 10 that receives power from the charging device 20 and stores the received power.

The charging device 20 is an example of an electronic device having a heat radiating sheet, but is not limited to such a configuration. The portable terminal 10, which includes wireless power reception device, may be included in the electronic device of the present example.

The charging device 20 is used to charge a battery of the portable terminal 10 by using a power receiving module 11 of the portable terminal 10.

The charging device 20 converts household alternating current power supplied from an external source into direct current power, converts the direct current power to an alternating current voltage of a specific frequency, and then transmits wireless power to the outside through a power transmitting module 30.

The charging device 20 includes a voltage converter 22, the power transmitting module 30, a case 50, and a heat radiating sheet 70.

The voltage converter 22 converts household alternating current power supplied from an external source into direct current power, converts the direct current power to an alternating current voltage of a specific frequency, and then supplies power to the power transmitting module 30. When the direct current power is directly supplied, the voltage converter 22 converts the supplied direct current power into an alternating current voltage of a specific frequency, and then supplies power to the power transmitting module 30.

The voltage converter 22 may be provided in the form of a circuit board on which electronic components are mounted, but is not limited to such a configuration.

The power transmitting module 30 transmits the power transmitted from the voltage converter 22 to the outside.

The power transmitting module 30 may include a magnetic portion 32 and a coil portion 35.

The magnetic portion 32 is formed in a flat plate shape (or a sheet shape), is disposed on one surface of the coil portion 35 and is fixedly attached to the coil portion 35. The magnetic portion 32 is provided for efficiently forming a magnetic path of a magnetic field generated by coil wiring of the coil portion 35. The magnetic portion 32 is formed of a material for easily forming the magnetic path, for example, a ferrite sheet may be used.

Meanwhile, although not shown, a metal sheet may be further added to an outer surface of the magnetic portion 32 in order to autonomously cut electromagnetic waves and magnetic flux leakage. The metal sheet may be formed of aluminum or the like, but is not limited to such a material.

The power receiving module 11 may include a magnetic portion 12 and a coil portion 15 similar to the magnetic portion 32 and the coil portion 35 of the power transmitting module 30, and may be configured similar to the power transmitting module 30.

The case 50 may be formed of an insulating resin material as a whole, and protect components included in the case 50 from the outside. For example, the case 50 may be formed of polycarbonate (PC) material, but is not limited to such a material.

The case 50 may be formed in a flat cylindrical shape or a rectangular parallelepiped shape and has an accommodation space in which the voltage converter 22, the power transmitting module 30, and the heat radiating sheet 70 may be accommodated.

The case 50 according to the example may be divided into an upper case forming a charging surface on which the portable terminal 10 is seated and a lower case coupled to a lower portion of the upper case to provide the accommodation space.

Since the upper case has the mobile terminal 10 mounted on an upper surface thereof, the upper surface is formed as a flat surface. The heat radiating sheet 70 is disposed on a lower surface (or an internal surface) of the upper case. Therefore, one surface of the heat radiating sheet 70 may be attached to the internal surface of the case 50, and another surface thereof may be attached to the coil portion 35.

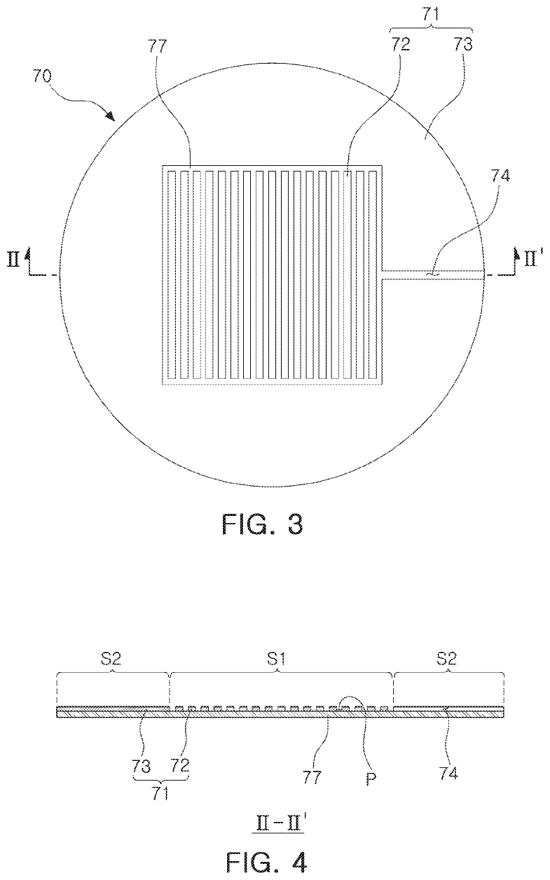

FIG. 3 is a plan view schematically showing the heat radiating sheet shown in FIG. 1. FIG. 4 is a cross-sectional view taken along line II-II′ of FIG. 3.

Referring to FIGS. 3 and 4, the heat radiating sheet 70 includes an insulating layer 77 and a conductive layer 71. Also, the heat radiating sheet 70 may be divided into a magnetic flux transfer portion S1 and a heat radiating portion S2 according to a position thereof.

The insulating layer 77 defines the overall area of the heat radiating sheet 70 and functions as a supporting member to which the conductive layer 71 is bonded and fixed.

The conductive layer 71 may be disposed on one surface of the insulating layer 77. The coil portion 35 of the power transmitting module 30 may be disposed in surface contact with another surface of the insulating layer 77.

The insulating layer 77 may be formed of an insulating film such as PET (polyethylene terephthalate), PC (polycarbonate), PES (polyethersulfone), PI (polyimide), PMMA (polymethlymethacrylate), COP (cycloolefin polymers), or the like, but is not limited to such materials.

In the example, since the charging device 20 is formed in a disc shape, the insulating layer 77 is also formed in a disc shape. Accordingly, if the charging device 20 is formed in a rectangular shape, the insulating layer 77 may also be formed in a rectangular shape.

The conductive layer 71 is attached to one surface of the insulating layer 77 and includes a plurality of line-type conductors 72 disposed in the magnetic flux transfer portion S1 and one area-type conductor 73 disposed in the heat radiating portion S2.

The magnetic flux transfer portion S1 is an area disposed in the center of the insulating layer 77 and may be defined as a region in which a wireless power signal (e.g., a magnetic field) is formed during a wireless charging process.

The plurality of line-type conductors 72 are disposed in the magnetic flux transfer portion S1. The line-type conductors 72 are spaced apart from the area-type conductor 73 and are spaced apart from each other by a certain distance. Thus, the line-type conductors 72 are electrically insulated from each other.

The line-type conductors 72 are arranged separately from each other by a certain gap P, and arranged in parallel. Accordingly, the wireless power signal may be smoothly transmitted to the portable terminal 10 by using the gap P between the line-type conductors 72.

Also, since the line-type conductors 72 are spaced apart from each other, it is possible to suppress the formation of a closed loop of the Eddy current in the magnetic flux transfer portion S1 during a wireless power transmission process, and thus a current loss due to the Eddy current may be minimized.

Therefore, the width or thickness of the line-type conductors 72, a distance of the gap P between the line-type conductors 72, and the like may be varied so as to reduce the Eddy current and improve heat radiation performance.

Meanwhile, in the example, the gap P between the line-type conductors 72 is formed as an empty space, but it is also possible to fill an insulating material in the gap P.

The magnetic flux transfer portion S1 is disposed at a position facing the coil portion 35 of the power transmitting module 30. Therefore, the area of the magnetic flux transfer portion S1 is formed to be the same as or similar to the area of the coil portion 35.

In the example, being disposed to oppose each other or to face each other means that the magnetic flux transfer portion S1 is disposed to overlap the coil portion 35 when the magnetic flux transfer portion S1 is projected onto the coil portion 35 in a state in which the magnetic flux transfer portion S1 is stacked on the coil portion 35.

Meanwhile, a region in which the magnetic flux transfer portion S1 substantially faces the coil portion 35 is a region in which coil wiring for wireless charging is disposed in the coil portion 35. Therefore, when the coil wiring is not disposed over the entire coil portion 35, but only over a part of the coil portion 35, the magnetic flux transfer portion S1 may be configured as an area corresponding to the region in which the coil wiring is disposed in the coil portion 35 other than the entire coil portion 35.

The heat radiating portion S2 is a region disposed along the circumference of the magnetic flux transfer portion S1 and may be defined as an area not facing the coil portion 35 or the coil wiring in the heat radiating sheet 70.

The area-type conductor 73, which may be configured as a single conductor, is disposed in the heat radiating portion S2. The area-type conductor 73 is disposed on a surface of the insulating layer 77 and is disposed over the entire periphery of the magnetic flux transfer portion S1. The heat radiating portion S2 may be defined as the entire region in which the area-type conductor 73 is disposed.

In the example, since the insulating layer 77 is formed in a disc shape, the area-type conductor 73 is formed in a circular ring shape along the circumference of the magnetic flux transfer portion S1, but is not limited to such a configuration. In a case in which the insulating layer 77 is formed in a rectangular shape, the area-type conductor 73 may also be formed in a circular ring shape.

Also, the circular ring shape formed by the area-type conductor 73 in the example is a ring shape having a part cut off by a cutting portion 74, and not a complete annular shape. However, the disclosure is not limited to such a configuration and includes a case in which the ring shape is formed as a complete annular shape.

Therefore, in the example, the meaning that the area-type conductor 73 is formed in the circular ring shape includes both a case in which the area-type conductor 73 is formed in a complete annular shape and a case in which the area-type conductor 73 is formed in a partially disconnected ring shape.

Since the area-type conductor 73 of the example is disposed along the circumference of the magnetic flux transfer portion S1, the area-type conductor 73 is disposed in a region in which a magnetic field is not present or is minimal during wireless charging. However, the Eddy current may also be generated in the area-type conductor 73 due to leakage flux. Therefore, in order to suppress the generation of the Eddy current in the area-type conductor 73, the heat radiating portion S2 is provided with the cutting portion 74.

The cutting portion 74 cuts the area-type conductor 73 in the radial direction of the area-type conductor 73. Therefore, the cutting portion 74 is formed as a linear slit connecting the magnetic flux transfer portion S1 and the outside of the area-type conductor 73.

The cutting portion 74 is formed in a partially disconnected ring shape, rather than a completely annular shape. Therefore, it is possible to prevent the Eddy current having a concentricity with the area-type conductor 73 from occurring in the area-type conductor 73.

The area-type conductor 73 may also be electrically connected to the ground of the charging device 20. The area-type conductor 73 may also provide a function of shielding electromagnetic waves.

The conductive layer 71 may be formed of a metal material having excellent electromagnetic wave transmittance and thermal diffusivity. For example, the conductive layer 71 may selectively use any one of materials such as copper, iron, nickel, tin, zinc, gold, silver, or the like, or alloys thereof.

In the example, the line-type conductors 72 and the area-type conductor 73 are both formed of the same material and disposed on the insulating layer 77 with a same thickness. However, the disclosure is not limited to such a material and configuration. For example, various configurations may be possible such as the line-type conductors 72 and the area-type conductor 73 may be formed of different materials or may have different thicknesses.

Meanwhile, although not shown, the heat radiating sheet 70 of the example may further include an adhesive layer. The adhesive layer bonds the heat radiating sheet 70 to a case of an electronic device or a power transmitting module. Thus, the adhesive layer may be added on the insulating layer 77 or on the conductive layer 71. The adhesive layer may include at least one or more of, as polymer resin, acrylic resin, epoxy resin, EPDM (Ethylene Propylene Diene Monomer) resin, CPE (chlorinated polyethylene) resin, silicone, polyurethane, urea resin, melamine resin, phenol resin and unsaturated ester resin.

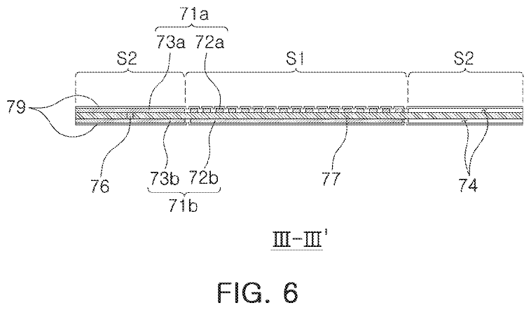

It is also possible to use a protective layer 79 shown in FIG. 6 as the adhesive member.

The heat radiating sheet 70 according to the example is disposed between the power transmitting module 30 and the power receiving module 11 to radiate heat generated from the power transmitting module 30 or the power receiving module 11.

Meanwhile, when a conductive material is disposed in the power transmitting module 30 and the power receiving module 11, the Eddy current is generated in the conductive material. In this case, the current loss may be increased.

Accordingly, the line-type conductors 72 of the example are configured to have a width narrower than a width at which a skin effect may occur. The heat radiating sheet 70 of the example is provided in electronic devices that perform wireless charging in a frequency band of 100 to 150 KHz. Therefore, the line-type conductors 72 of the example are configured to have a line width of 200 μm or less. Since the magnetic flux used for wireless charging passes through the line-type conductors 72, the charging efficiency is not affected. Also, since the line-type conductors 72 are configured to have fine line widths, the generation of the Eddy current is suppressed, and loss due to the Eddy current may be minimized.

The heat generated from the power transmitting module 30 or the power receiving module 11 is quickly radiated to the outside of the heat radiating sheet 70 through the line-type conductors 72 and the area-type conductor 73, and thus the heat may be effectively removed.

Also, since the line-type conductors 72 are arranged to cross the magnetic flux forming portion S1, the heat generated in the magnetic flux transfer portion S1 is rapidly moved along the longitudinal axes of the line-type conductors 72 through the line-type conductors 72. Therefore, the heat radiating effect may be enhanced.

Also, the conductive layer 71 of the heat radiating sheet 70 may also perform a function of removing noise generated during the wireless charging process, thereby performing a function of an electromagnetic wave shielding filter as well as the heat dissipation function.

Meanwhile, in the example, although the conductive layer 71 is disposed on the insulating layer 77, the disclosure is not limited to such a configuration. For example, it is also possible to arrange an insulating layer between the plurality of line-type conductors 72 constituting the conductive layer 71 and the area-type conductor 73. In this configuration, the insulating layer is disposed on the same plane as the conductive layer 71, and has a function of physically connecting the line-type conductors 72, spaced apart from each other and the area-type conductor 73, and simultaneously electrically maintaining the insulation.

It is also possible to omit the insulating layer and to configure the line-type conductors 72 and the area-type conductor 73 to be directly attached to the coil portion 35 of the power transmitting module 30.

Meanwhile, the disclosure is not limited to the above-described configurations, and various configurations are possible.

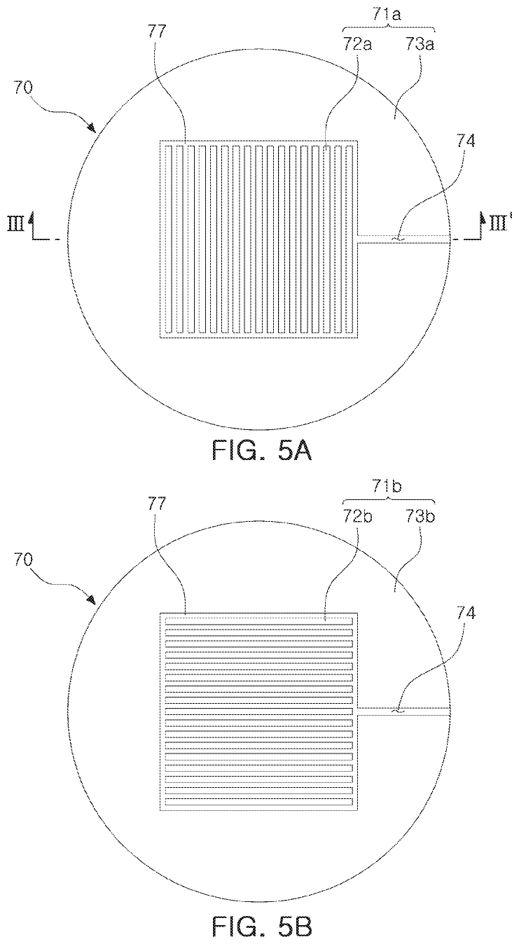

FIGS. 5A and 5B are a plan view and a rear view illustrating the heat radiating sheet 70 according to an example. FIG. 6 is a cross-sectional view taken along line III-III′ of FIG. 5. FIG. 5A is a plan view of the heat radiating sheet 70, and FIG. 5B illustrates a rear surface of the heat radiating sheet 70 rotated with respect to an axis of III-III′ of FIG. 5A.

Referring to FIGS. 5A to 6, in the heat radiating sheet 70 of the example, conductive layers 71a and 71b are disposed on both surfaces of the insulating layer 77, respectively.

A first conductive layer 71a disposed on a first surface of the insulating layer 77 includes a first line-type conductor 72a and a first area-type conductor 73a. The first line-type conductor 72a and the first area-type conductor 73a of the first conductive layer 71a are configured in the same manner as the line-type conductor 72 of FIG. 4 and the area-type conductor 73 of FIG. 4, and thus detailed descriptions thereof are omitted.

A second conductive layer 71b disposed on a second surface of the insulating layer 77 includes a second line-type conductor 72b and the second area-type conductor 73b.

The second area-type conductor 73b may be formed in a similar or identical shape to the first area-type conductor 73a. For example, when the first area-type conductor 73a is projected onto the second area-type conductor 73b, the first area-type conductor 73a and the second area-type conductor 73b may overlap in the same shape. However, the disclosure is not limited to such a configuration. Various configurations may be possible, for example, a direction of the cutting portion 74 is differently arranged or a size of the cutting portion 74 is differently formed.

The second line-type conductor 72b is configured similarly to the first line-type conductor 72a, but is disposed in a direction different from the first line-type conductor 72a.

More specifically, when the first line-type conductor 72a is disposed in a first direction (e.g., a direction perpendicular to the cutting portion 74) with respect to the longitudinal direction, the second line-type conductor 72b may be disposed in a second direction (e.g., the same direction as the cutting portion 74) different from the first direction.

In the example, the first direction and the second direction are at right angles to each other. Therefore, when the second line-type conductor 72b is disposed at right angles to the first line-type conductor 72a and is projected on the first line-type conductor 72a, the second line-type conductor 72b and the first line-type conductor 72a may overlap in a lattice shape.

However, the disclosure is not limited to such a configuration. An angle between the first direction and the second direction may be configured as various angles such as 30°, 45°, or 60°. It is also possible to configure the first direction and the second direction in the same direction.

Since the insulating layer 77 is disposed between the first line-type conductor 72a and the second line-type conductor 72b, the first line-type conductor 72a and the second line-type conductor 72b are not electrically connected to each other. However, since each of the first area-type conductor 73a and the second area-type conductor 73b may be electrically connected to the ground of the charging device 20, the first area-type conductor 72a and the second area-type conductor 72b may be electrically connected to each other.

The first area-type conductor 72a and the second area-type conductor 72b may be electrically connected to each other through an interlayer connection conductor 76 provided in the insulating layer 77. However, the disclosure is not limited to such a configuration.

Also, in the example, the first conductive layer 71a and the second conductive layer 71b are provided in both the magnetic flux transfer portion S1 and the heat radiating portion S2. However, the disclosure is not limited to such a configuration. Various configurations may be possible, for example, the first conductive layer 71a and the second conductive layer 71b may be disposed only in the magnetic flux transfer portion S1 and any one of the first conductive layer 71a and the second conductive layer 71b may be disposed in the heat radiating portion S2 or vice versa.

In the example, a protective layer 79 may be added to the surfaces of the first conductive layer 71a and the second conductive layer 71b. The protective layer 79 may be formed of an insulating film similar to the insulating layer 77 and may be configured as the same material as the insulating layer 77.

In the example, the protective layer 79 is disposed on the surfaces of both the first conductive layer 71a and the second conductive layer 71b. However, various configurations may be possible, for example, the protective layer 79 is disposed on only one of the first conductive layer 71a and the second conductive layer 71b.

When the heat radiating sheet 70 is configured as in the example, heat is radiated by the first conductive layer 71a and the second conductive layer 71b. Also, heat is quickly transferred in two different directions by the first line-type conductor 72a and the second line-type conductor 72b, thereby increasing the heat radiation effect.

Also, since the conductive layers 71a and 71b are stacked in two layers, the electromagnetic wave shielding effect may be increased.

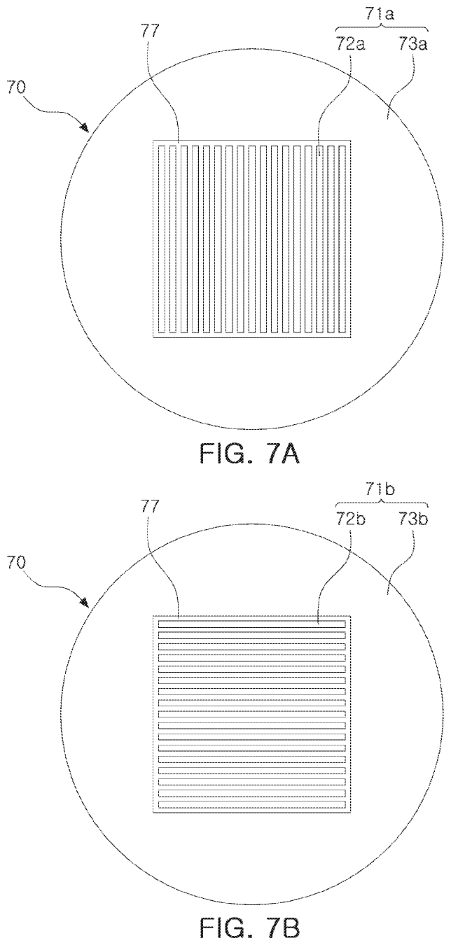

FIGS. 7A and 7B are a plan view and a rear view illustrating the heat radiating sheet 70 according to an example. Here, FIG. 7A is a plan view of the heat radiating sheet 70, and FIG. 7B illustrates a rear surface of the heat radiating sheet 70 rotated with respect to the axis of III-III′ in FIG. 5A.

The heat radiating sheet 70 shown in FIGS. 7A and 7B is configured similarly to the heat radiating sheet 70 shown in FIGS. 5A and 5B and differs in that the cutting portion (74 in FIG. 5A) is omitted in the heat radiating portion S2.

If the cutting portion is omitted, there is a possibility that the Eddy current is generated in the area-type conductors 73a and 73b disposed in the heat radiating portion S2. However, if the heat radiating portion S2 is sufficiently spaced apart from the coil portion (35 of FIG. 2) or coil wiring, the cutting portion may be omitted.

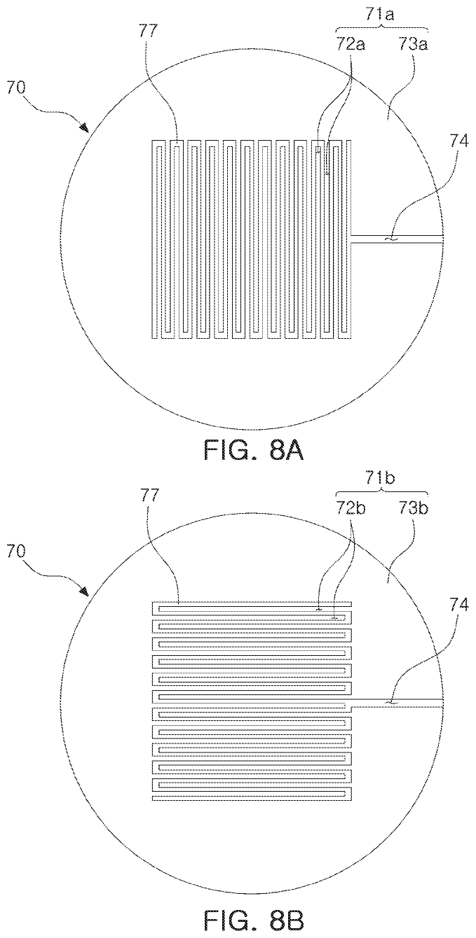

FIGS. 8A and 8B are a plan view and a rear view illustrating the heat radiating sheet 70 according to an example. Here, FIG. 8A is a plan view of the heat radiating sheet 70, and FIG. 8B illustrates a rear surface of the heat radiating sheet 70 rotated with respect to the axis of III-III′ in FIG. 5A.

Referring to FIGS. 8A and 8B, the heat radiating sheet 70 according to the example has the line-type conductors 72a and 72b all connected to the area-type conductors 73a and 73b. Thus, all the line-type conductors 72a and 72b are also electrically connected to the ground of the charging device 20.

Also, in the example, both ends of the line-type conductors 72a and 72b are not connected to the area-type conductors 73a and 73b, and only one end of the line-type conductors 72a and 72b is connected to the area-type conductors 73a and 73b. Both ends of the line-type conductors 72a and 72b are alternately connected to the area-type conductors 73a and 73b. For example, a first end of the line-type conductor 72a is connected to the area-type conductor 73a, and second ends of all the line-type conductors 72a disposed in both sides of the line-type conductor 72a are connected to the area-type conductor 73a.

With the above configuration, formation of a closed loop path in the conductive layers 71a and 71b may be suppressed.

In the example, the two conductive layers 71a and 71b are disposed on both sides of the insulating layer 77, and the first line-type conductor 72a and the second line-type conductor 72b are arranged in different directions. However, the disclosure is not limited to such a configuration. It is also possible to configure only one conductive layer to be included on one surface of the insulating layer 77, as in the example of FIG. 3.

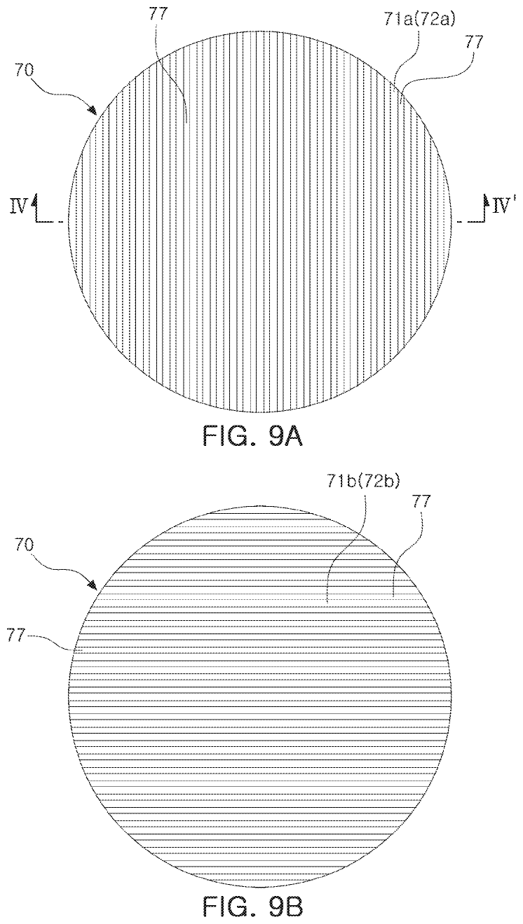

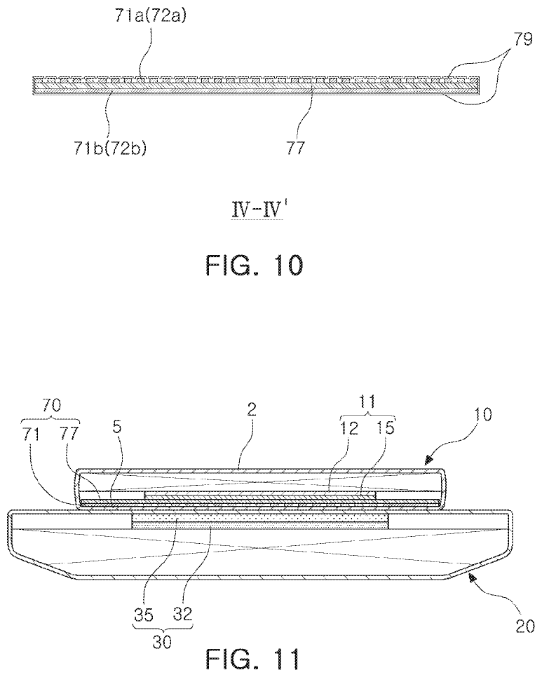

FIGS. 9A and 9B are a plan view and a rear view illustrating the heat radiating sheet 70 according to an example. FIG. 10 is a cross-sectional view taken along line IV-IV′ of FIG. 9A. FIG. 9A is a plan view of the heat radiating sheet 70, and FIG. 9B illustrates a rear surface of the heat radiating sheet 70 rotated with respect to the axis of III-III′ in FIG. 5A.

Referring to FIGS. 9 and 10, the heat radiating sheet 70 according to the example does not have a heat radiating portion and is configured as only a magnetic flux transfer portion.

The heat radiation performance may be somewhat reduced as compared with other examples, but the generation of the Eddy current may be suppressed at the maximum and thus the current loss may be minimized.

Meanwhile, in the example, the two conductive layers 71a and 71b are disposed on both sides of the insulating layer 77, and the first line-type conductor 72a and the second line-type conductor 72b are arranged in different directions. However, the disclosure is not limited to such a configuration. Various configurations are possible, such as one surface of the insulating layer 77 is configured to include only one conductive layer as in the example of FIG. 3 or the first line-type conductor 72a and the second line-type conductor 72b are arranged in the same direction.

FIG. 11 is a cross-sectional view schematically showing an electronic device according to an example.

Referring to FIG. 11, the electronic device according to the example is a portable terminal 10 having a heat radiating sheet 70 that may receive and store power supplied from the charging device 20 wirelessly.

The portable terminal 10 includes a terminal body 2, a power receiving module 11, a case 5, and a heat radiating sheet 70.

The power receiving module 11 and the heat radiating sheet 70 are accommodated in an inner space formed by the terminal body 2 and the case 5.

The terminal body 2 includes various elements for driving electronic devices such as a circuit board, a display, and a battery.

The power receiving module 11 may include a magnetic portion 12 and a coil portion 15 similar to the power transmitting module 30 of FIG. 2 and may be configured similar to the power transmitting module 30 described above, in which the power transmitting module 30 may include a magnetic portion 32 and a coil portion 35.

The power receiving module 11 is disposed between the case 5 and the terminal body 2. The magnetic portion 12 of the power receiving module 11 is positioned on the side of the terminal body 2, and the coil portion 15 is disposed between the magnetic portion 12 and the case 5.

The case 5 may be entirely formed of an insulating resin material or a conductive material and protects components included therein from the outside.

The heat radiating sheet 70 is disposed between the coil portion 15 and the case 5. Although the heat radiating sheet 70 shown in FIG. 4 is used in the drawing, the disclosure is not limited to such a configuration. Any one heat radiating sheet in the embodiments described above may be selectively used.

Accordingly, heat generated in the coil portion 15 of the portable terminal 10 is diffused to the entirety of the case 5 through the heat radiating portion S2 and discharged to the outside of the portable terminal 10.

Although the heat radiating sheet 70 is disposed inside the portable terminal 10 in the example, it is also possible to dispose the heat radiating sheet 70 on an outer surface of the case 5.

Also, the portable terminal 10 in the example refers to a mobile phone (or a smart phone), but the disclosure is not limited to such a device. Any electronic device such as a notebook computer, a tablet PC, a wearable device, or the like, capable of being portable and performing wireless communication may be included.

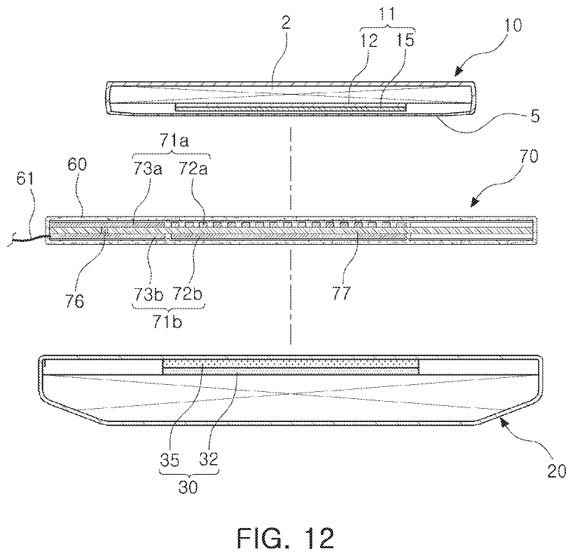

FIG. 12 is a cross-sectional view schematically showing the heat radiating sheet 70 according to an example.

Referring to FIG. 12, the heat radiating sheet 70 according to the example is independently formed without being coupled to an electronic device.

The heat radiating sheet 70 may be manufactured by using a separate substrate and disposed between the portable terminal 10 and the charging device 20 when the portable terminal 10 is charged.

A separate connecting member 61 may be included to connect the area-type conductor 73b to the ground. As the connecting member 61, wiring such as insulated wiring may be used and may have one end connected to the area-type conductor 73b and another end connected to the external ground from the outside of the heat radiating sheet 70.

The heat radiating sheet 70 shown in FIG. 6 is used in the example of FIG. 12, but the disclosure is not limited to such a configuration. Any heat radiating sheet in the examples described above may be selectively used.

Also, the heat radiating sheet 70 of the example may be provided with a protective member 60 for protecting the insulating layer 77 and the conductive layers 71a and 71b from the external environment. The protective member 60 may provide an accommodation space in which the insulating layer 77 and the conductive layers 71a and 71b are arranged and may be formed of an insulating material.

For example, the protective member 60 may be disposed on the surfaces of the insulating layer 77 and the conductive layers 71 and 71b in the form of a film, or may be formed of a hard resin material. However, the disclosure is not limited to such a material and such a configuration. The protective member 60 may be omitted.

As set forth above, the heat radiating sheet and the electronic device including the heat radiating sheet may minimize the current loss due to the Eddy current to maintain the wireless transmissions efficiency and enable efficient heat radiation.

While examples have been shown and described above, it will be apparent to those skilled in the art that modifications and variations could be made without departing from the scope in the present disclosure as defined by the appended claims.

For example, although the heat radiating sheet having only one insulating layer has been described as an example, the configuration of the present disclosure is not limited thereto. It is possible to configure an insulating layer as a plurality of layers, and also possible to configure a plurality of conductive layers between the insulating layers.

Also, the above-described examples may be implemented in combination with each other.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. An electronic device comprising:
a power module configured to transmit or receive power wirelessly and comprising a coil portion configured to generate a magnetic field; and
a heat radiating sheet disposed on one side of the and comprising line-type conductors arranged to overlap the coil portion and an area-type conductor disposed along a periphery of the line-type conductors.

2. The electronic device of claim 1, wherein the heat radiating sheet further comprises a cutting portion comprising a cut in a radial direction of the area-type conductor.

3. The electronic device of claim 1, wherein the area-type conductor is electrically connected to ground.

4. The electronic device of claim 1, wherein the heat radiating sheet further comprises an insulating layer attached to the line-type conductors and the area-type conductor.

5. The electronic device of claim 4, wherein the line-type conductors include first line-type conductors attached to a first surface of the insulating layer and second line-type conductors attached to a second surface of the insulating layer, and the area-type conductor includes a first area-type conductor attached to the first surface of the insulating layer and a second area-type conductor attached to the second surface of the insulating layer.

6. The electronic device of claim 5, wherein the first line-type conductors and the second line-type conductors face in different directions.

7. The electronic device of claim 5, wherein the heat radiating sheet further comprises an interlayer connection conductor electrically connecting the first area-type conductor and the second area-type conductor.

8. The electronic device of claim 1, wherein one end of each of the line-type conductors is connected to the area-type conductor.

9. The electronic device of claim 8, wherein the line-type conductors each include a first end and a second end opposite the first end, and the line-type conductors are arranged such that first line-type conductors having the first end connected to the area-type conductor are alternated with second line-type conductors having the second end connected to the area-type conductor.

10. The electronic device of claim 1, wherein each of the line-type conductors has a line width of 200 μm or less.

11. The electronic device of claim 1, wherein the line-type conductors and the area-type conductor are formed of a same material.

12. The electronic device of claim 1, wherein the line-type conductors are spaced apart from each other so as not to contact each other.

13. The electronic device of claim 1, further comprising a case configured to accommodate the coil portion and the heat radiating sheet therein,
wherein a first surface of the heat radiating sheet is attached to an internal surface of the case and a second surface of the heat radiating sheet is attached to the coil portion.

14. A heat radiating sheet for wireless charging disposed between a power transmitting module and a power receiving module, the heat radiating sheet comprising:
an insulating layer;
first line-type conductors disposed on a first surface of the insulating layer and electrically disconnected from each other; and
second line-type conductors disposed on a second surface of the insulating layer and electrically disconnected each other, and electrically disconnected from the first line-type conductors.

15. The heat radiating sheet of claim 14, wherein the first line-type conductors are arranged to have longitudinal axes directed in a first direction and the second line-type conductors are arranged to have longitudinal axes directed in a second direction that is different from the first direction.

16. The heat radiating sheet of claim 14, further comprising an area-type conductor disposed along a periphery of either the first line-type conductors or a periphery of the second line-type conductors.

17. The heat radiating sheet of claim 16, further comprising a cut in the area-type conductor in a radial direction of the area-type conductor.

18. An apparatus comprising:
a coil layer comprising coil wiring configured to generate a magnetic field;
a magnetic layer disposed on a first surface of the coil layer;
an insulating layer disposed on a second surface of the coil layer; and
a conductive layer comprising line-type conductors disposed parallel to each other on the insulating layer and arranged to overlap the coil wiring.

19. The apparatus of claim 18, wherein the conductive layer further comprises an area-type conductor disposed on the insulating layer and arranged along a periphery of an area in which the line-type conductors overlap the coil wiring.

20. The apparatus of claim 19, further comprising a cutting portion that cuts the area-type conductor in a radial direction, wherein the cutting portion is a linear slit connecting the area in which the line-type conductors overlap the coil wiring and an area outside of the area-type conductor.
